(19) United States
(12) Patent Application Publication
(10) Pub. No.: US 2025/0208214 A1
(43) Pub. Date: Jun. 26, 2025

(54) VIRTUAL SENSING CELL STATE OF CHARGE ESTIMATION FOR BATTERY PACK

(71) Applicant: GM GLOBAL TECHNOLOGY OPERATIONS LLC, Detroit, MI (US)

(72) Inventors: Cheng Peng, Shanghai (CN); Chengwu Duan, Shanghai (CN); Jian Yao, Shanghai (CN); Jun-mo Kang, Ann Arbor, MI (US); Madhusudan Raghavan, West Bloomfield, MI (US)

(73) Assignee: GM GLOBAL TECHNOLOGY OPERATIONS LLC, Detroit, MI (US)

(21) Appl. No.: 18/420,853

(22) Filed: Jan. 24, 2024

(30) Foreign Application Priority Data
Dec. 22, 2023 (CN) 202311782516.1

(51) Int. Cl. G01R 31/367; B60L 58/12; G01R 31/3842

(52) U.S. Cl. CPC G01R 31/367; B60L 58/12; G01R 31/3842; B60L 2240/547; B60L 2240/549

(57) ABSTRACT

A battery monitoring system for a battery pack of an electric vehicle. The battery monitoring system may include a virtual cell model configured for generating a definitive output based on a current through the battery pack and a definitive equivalent circuit model (ECM) for a virtual cell and a physical cell model configured for generating an indefinitive output based on the current and an indefinitive ECM for the battery pack. The battery monitoring system may include an SOC transformation module configured for generating a battery SOC for the battery pack based at least in part on the definitive and indefinitive outputs.

### CROSS-REFERENCE TO RELATED APPLICATIONS

This application claims priority to and the benefit of Chinese Patent Application No. 202311782516.1, which was filed on Dec. 22, 2023, and which is hereby incorporated by reference in its entirety.

### INTRODUCTION

The present disclosure relates to battery monitoring systems, such as but not necessarily limited to a battery monitoring system including a virtual sensing cell model operable for facilitating estimation of a state of charge (SOC) for a vehicle based battery pack.

A vehicle may include an electric motor for converting electrical power to mechanical power for purposes of utilizing the mechanical power to perform work, such as to mechanically power a drivetrain to propel the vehicle. Such vehicles may include a battery pack for storing and supplying electrical power for the electric motor, with the battery packs typically comprised of a plurality of battery cells arranged into one or more battery modules. The battery cells may include electrolytic or other types of materials operable for storing and supplying electrical power. The types of materials used for the battery cells may vary widely depending on various design considerations, output characteristics, performance parameters, etc., with one of the more favorable types of materials being Lithium Iron Phosphate (LFP). LFP battery cells may be desirable due to having a relatively strong thermal stability and other desirable characteristics. The use thereof may be complicated due to LFP batteries tending to have a relatively flat open circuit voltage state of charge (OCV-SOC) curve compared to battery cells having other types of materials with more pronounced OCV-SOC curves, such as Nickel Cobalt Manganese (NCM) battery cells. The relatively flat OCV-SOC curves may result in SOC estimates for the corresponding battery cells being more difficult to obtain with desired levels of accuracy relative to battery cells having more pronounced OCV-SOC curves.

### SUMMARY

One non-limiting aspect of the present disclosure relates to a battery monitoring system operable for estimating a state of charge (SOC) for a battery pack comprised entirely or partially of battery cells having a relatively flat open circuit voltage state of charge (OCV-SOC) curve, such as a Lithium Iron Phosphate (LFP) battery cells. The battery monitoring system may be configured with a virtual cell model operable for facilitating estimation of SOC for the battery pack based on the virtual cell model being defined relative to a battery cell material having a comparatively more pronounced OCV-SOC curve, such as Nickel Cobalt Manganese (NCM) battery cell. The virtual cell model may be used for generating a definitive output useful in estimating the SOC of the battery pack without requiring the battery pack to physically include an actual NCM or other battery cell comprised of a material with the more pronounced OCV-SOC curve. The battery monitoring system may additionally include a physical cell model operable for generating an indefinitive output for facilitating estimation of SOC based on the physical cell model being defined relative to a material of the actual physical battery cells included within the battery pack, such as for the LFP battery cells having the relatively flat OCV-SOC curve. The battery monitoring system may utilize the definitive and indefinitive outputs of the virtual and physical cell models to generate an estimation of SOC with desired levels of accuracy and size for greater accuracy than would be typically available based solely on a relatively flat OCV-SOC curve.

One non-limiting aspect of the present disclosure relates to a battery monitoring system for a battery pack of a vehicle. The battery monitoring system may include a sensing system configured for measuring a current (I) through the battery pack and a battery voltage (U_{t,P}) across the battery pack. The battery monitoring system may include a virtual cell model configured for generating a definitive output based on the current (I) and a definitive equivalent circuit model (ECM) for a virtual cell, with the definitive ECM defining a plurality of virtual parameters (Parameters_{V}) for the virtual cell and the definitive output including a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell. The battery monitoring system may include a physical cell model configured for generating an indefinitive output based on the current (I) and an indefinitive ECM for the battery pack, with the indefinitive ECM defining a plurality of physical parameters (Parameters_{P}) for the battery pack and the indefinitive output including an physical cell voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack. The battery monitoring system may include a voltage transformation module configured for generating a virtual voltage (U_{t,V}) based on the battery voltage (U_{t,P}) and the definitive and indefinitive outputs, a virtual cell SOC estimator configured for determining the virtual cell SOC (SOC_{V}) based on the virtual cell voltage (U_{t,V}), and the current (I) and an SOC transformation module configured for generating a battery SOC (SOC_{P}) for the battery pack based on the virtual cell SOC (SOC_{V}).

The virtual cell, at a time step k, model may be configured for determining the virtual cell voltage (U_{RC,V}(k)) according to:

$${U}_{RC , V} ( k ) = {e}^{- \frac{Δ t}{{R}_{1 , V} {C}_{1 , V}}} {U}_{RC , V} ( k - 1 ) + {R}_{1 , V} ( 1 - {e}^{- \frac{Δ t}{{R}_{1 , V} {C}_{1 , V}}} ) I ( k ) ,$$

wherein the virtual parameters (Parameters_{V}) include R_{1,V} and C_{1,V}.

The virtual cell model, at the time step k, may be configured for determining the virtual cell OCV (OCV_{V}(k)) based on the virtual cell SOC (SOC_{V}(k-1)) at a time step k-1.

The physical cell model, at the time step k, may be configured for determining the physical cell voltage (U_{RC,P}(k)) according to:

$${U}_{RC , P} ( k ) = {e}^{- \frac{Δ t}{{R}_{1 , P} {C}_{1 , P}}} {U}_{RC , P} ( k - 1 ) + {R}_{1 , P} ( 1 - {e}^{- \frac{Δ t}{{R}_{1 , P} {C}_{1 , P}}} ) I ( k ) ,$$

wherein the physical parameters (Parameters_{P}) include R_{1,P} and C_{1,P}.

The physical model, at the time step k, may be configured for determining the physical cell OCV (OCV_{P}(k)) based on the physical cell SOC (SOC_{P}(k-1)) at a time step k-1.

The voltage transformation module may be configured for determining the virtual cell voltage (U_{t,V}) according to:

$${U}_{t , V} ( k ) = {OCV}_{V} ( k ) - {U}_{RC , V} ( k ) + \frac{{R}_{0 , V}}{{R}_{0 , P}} ( {U}_{t , P} ( k ) - {OCV}_{P} ( k ) + {U}_{RC , P} ( k ) )$$

wherein the virtual parameters (Parameters_{V}) include R_{0,V} and the physical parameters (Parameters_{P}) include R_{0,P}.

A Kalman Filter, at the time step k, may be configured for determining the virtual cell SOC (SOC_{V}(k)) based on the virtual cell voltage (U_{t,V}(k)) and the current (I(k)).

The SOC transformation module, at the time step k, may be configured for determining the battery SOC (SOC_{P}(k)) according to:

$${SOC}_{P} ( k ) = \frac{{Q}_{V}}{{Q}_{P}} [ {SOC}_{V} ( k ) - ( 1 - \frac{{Q}_{P}}{{Q}_{V}} ) ]$$

wherein the physical parameters (Parameters_{P}) include Q_{P} and the virtual parameters (Parameters_{V}) include Q_{V}.

One non-limiting aspect of the present disclosure relates to a non-transitory computer-readable storage medium for storing a plurality of non-transitory instructions, which when executed with one or more processors, are operable for monitoring a battery pack. The non-transitory instructions may be operable for: determining a current (I) through the battery pack and a battery voltage (U_{t,P}) across the battery pack; generating a definitive output based on the current (I) and a definitive equivalent circuit model (ECM) for a virtual cell, the definitive ECM defining a plurality of virtual parameters (Parameters_{V}) for the virtual cell, the definitive output including a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell; and generating an indefinitive output based on the current (I) and an indefinitive ECM for the battery pack, the indefinitive ECM defining a plurality of physical parameters (Parameters_{P}) for the battery pack, the indefinitive output including an indefinitive voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack.

The non-transitory instructions may be operable for: generating a virtual voltage (U_{t,V}) based on the battery voltage (U_{t,P}), and the definitive and indefinitive outputs; determining the virtual cell SOC (SOC_{V}) based on the virtual cell voltage (U_{t,V}) and the current (I); and generating a battery SOC (SOC_{P}) for the battery pack based on the virtual cell SOC (SOC_{V}).

The non-transitory instructions may be operable for, at a time step k, determining the virtual cell voltage (U_{RC,V}(k)) according to:

$${U}_{RC , V} ( k ) = {e}^{- \frac{Δ t}{{R}_{1 , V} {C}_{1 , V}}} {U}_{RC , V} ( k - 1 ) + {R}_{1 , V} ( 1 - {e}^{- \frac{Δ t}{{R}_{1 , V} {C}_{1 , V}}} ) I ( k )$$

wherein the virtual parameters (Parameters_{V}) include R_{1,V} and C_{1,V}.

The non-transitory instructions may be operable for, at the time step k, determining the virtual cell OCV (OCV_{V}(k)) based on the virtual cell SOC (SOC_{V}(k-1)) at a time step k-1.

The non-transitory instructions may be operable for, at the time step k, determining the physical cell voltage (U_{RC,P}(k)) according to:

$${U}_{RC , P} ( k ) = {e}^{- \frac{Δ t}{{R}_{1 , P} {C}_{1 , P}}} {U}_{RC , P} ( k - 1 ) + {R}_{1 , P} ( 1 - {e}^{- \frac{Δ t}{{R}_{1 , P} {C}_{1 , P}}} ) I ( k )$$

wherein the physical parameters (Parameters_{P}) include R_{1,P} and C_{1,P}.

The non-transitory instructions may be operable for, at the time step k, determining the physical cell OCV (OCV_{P}(k)) based on the physical cell SOC (SOC_{P}(k-1)) at a time step k-1.

The non-transitory instructions may be operable for determining the virtual cell voltage (U_{t,V}) according to:

$${U}_{t , V} ( k ) = {OCV}_{V} ( k ) - {U}_{RC , V} ( k ) + \frac{{R}_{0 , V}}{{R}_{0 , P}} ( {U}_{t , P} ( k ) - {OCV}_{P} ( k ) + {U}_{RC , P} ( k ) )$$

wherein the virtual parameters (Parameters_{V}) include R_{0,V} and the physical parameters (Parameters_{P}) include R_{0,P}.

The non-transitory instructions may be operable for, at the time step k, determining the virtual cell SOC (SOC_{V}(k)) based on the virtual cell voltage (U_{t,V}(k)) and the current (I(k)).

The non-transitory instructions may be operable for, at the time step k, determining the battery SOC (SOC_{P}(k)) according to:

$${SOC}_{P} ( k ) = \frac{{Q}_{V}}{{Q}_{P}} [ {SOC}_{V} ( k ) - ( 1 - \frac{{Q}_{P}}{{Q}_{V}} ) ]$$

wherein the physical parameters (Parameters_{P}) include Q_{P} and the virtual parameters (Parameters_{V}) include Q_{V}.

One non-limiting aspect of the present disclosure relates to a battery monitoring system for a battery pack of an electric vehicle. The battery monitoring system may include a virtual cell model configured for generating a definitive output based on a current (I) through the battery pack and a definitive equivalent circuit model (ECM) for a virtual cell, a physical cell model configured for generating an indefinitive output based on the current (I) and an indefinitive ECM for the battery pack, and an SOC transformation module configured for generating a battery SOC (SOC_{P}) for the battery pack based at least in part on the definitive and indefinitive outputs.

The definitive ECM may define a plurality of virtual parameters (Parameters_{V}) for the virtual cell, the definitive output may include a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell, the indefinitive ECM may define a plurality of physical parameters (Parameters_{P}) for the battery pack, and the indefinitive output may include an indefinitive voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack.

The battery monitoring system may include a voltage transformation module configured for generating a virtual voltage (U_{t,V}) based on the battery voltage (U_{t,P}) and the definitive and indefinitive outputs, a virtual cell SOC estimator configured for determining the virtual cell SOC (SOC_{V}) based on the virtual cell voltage (U_{t,V}) and the current (I), and an SOC transformation module configured for generating the battery SOC (SOC_{P}) for the battery pack based on the virtual cell SOC (SOC_{V}).

These features and advantages, along with other features and advantages of the present teachings, may be readily apparent from the following detailed description of the modes for carrying out the present teachings when taken in connection with the accompanying drawings. It should be understood that even though the following figures and embodiments may be separately described, single features thereof may be combined to additional embodiments.

### BRIEF DESCRIPTION OF THE DRAWINGS

The accompanying drawings, which may be incorporated into and constitute a part of this specification, illustrate implementations of the disclosure and together with the description, serve to explain the principles of the disclosure.

FIG. 1 illustrates a schematic view of a vehicle in accordance with one non-limiting aspect of the present disclosure.

FIG. 2 illustrates a schematic diagram of a battery monitoring system in accordance with one non-limiting aspect of the present disclosure.

FIG. 3 illustrates a flowchart of a method for monitoring a battery pack in accordance with one non-limiting aspect of the present disclosure.

FIG. 4 illustrates a pronounced OCV-SOC curve in accordance with one non-limiting aspect of the present disclosure.

FIG. 5 illustrates an example of such a relative flat OCV-SOC curve FIG. 5 illustrates an example of such a relative flat OCV-SOC curve, with a vertical axis indicating OCV (V) and a horizontal axis indicating SOC (%).

### DETAILED DESCRIPTION

As required, detailed embodiments of the present disclosure may be disclosed herein; however, it may be understood that the disclosed embodiments may be merely exemplary of the disclosure that may be embodied in various and alternative forms. The figures may not be necessarily to scale; some features may be exaggerated or minimized to show details of particular components. Therefore, specific structural and functional details disclosed herein may need not to be interpreted as limiting, but merely as a representative basis for teaching one skilled in the art to variously employ the present disclosure.

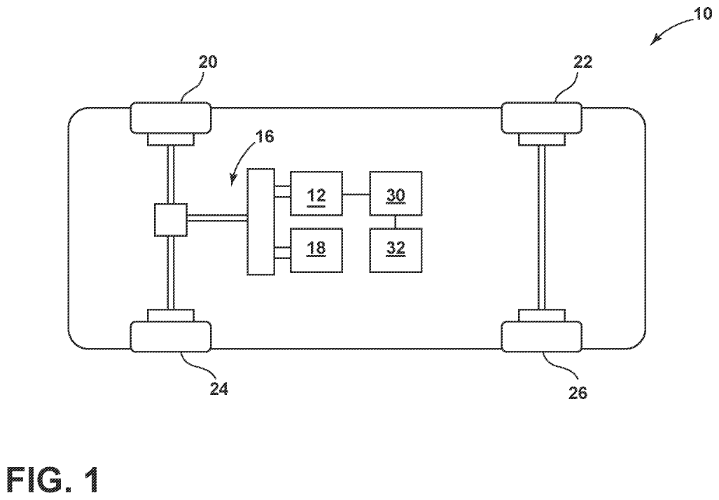

FIG. 1 illustrates a schematic view of a vehicle 10 in accordance with one non-limiting aspect of the present disclosure. The vehicle 10, which may be interchangeable referred to as an electric or hybrid vehicle 10, may include an electric motor 12 operable for converting electrical power to mechanical power for purposes of utilizing the mechanical power to perform work, such as to mechanically power a drivetrain to propel the vehicle. The vehicle 10 is illustrated as a hybrid type due to the powertrain 16 optionally including an internal combustion engine (ICE) 18 for generating mechanical power. The powertrain 16 may include a transmission, a driveshaft, a differential, axles and/or other componentry to facilitate conveying rotative force from a rotor shaft coupled with a rotor to one or more of the wheels 20, 22, 24, 26. The vehicle 10 may include a battery pack 30 operable for storing and supplying electrical power for the electric motor 12 and/or other system, buses, etc. on board the vehicle. Particularly when the vehicle 10 is propelled solely by the electric motor 12, the battery pack 30 may be comprised of a plurality of battery cells arranged into a plurality of battery modules. The vehicle 10 may include a battery monitoring system 32 to facilitate monitoring, controlling, measuring, and otherwise directing operation, performance, etc. for the battery pack 30.

The battery pack 30 may include the battery cells being comprised of a wide variety of materials operable for facilitating the storage and supply of electrical power, and as such, the present disclosure is not intended to be limited to a particular battery material, chemistry, etc. The types of materials used for the battery cells may vary widely depending on various design considerations, output characteristics, performance parameters, etc., with one of the more favorable types of materials being Lithium Iron Phosphate (LFP) due to LFP batteries tending to have a relatively strong thermal stability and other desirable characteristics. The present disclosure is predominantly described with respect to the battery pack 30 being of a homogeneous type whereby the battery cells may each having the same type of material and/or chemistry. This is done for exemplary and non-limiting purposes as the present disclosure fully contemplates the battery pack being of a heterogeneous type whereby the battery cells may have mixed chemistries and/or different battery cells having differing types of materials. With respect to the use of LFP battery cells or other battery cells of the like, the use thereof may be complicated due the materials tending to have a relatively flat open circuit voltage state of charge (OCV-SOC) curve relative to battery cells having other types of materials with more pronounced OCV-SOC curves, such as Nickel Cobalt Manganese (NCM) battery cells. The relatively flat OCV-SOC curves may tend to result in SOC or other estimates, calculations, etc. for the corresponding battery cells and/or battery pack being more difficult to obtain with desired levels of accuracy relative to those having more pronounced OCV-SOC curves.

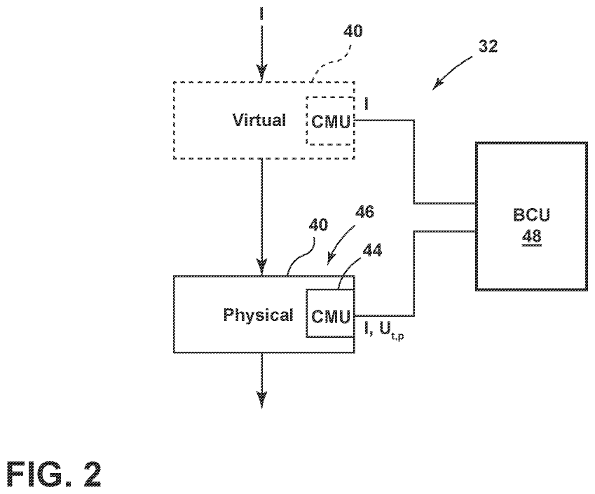

FIG. 2 illustrates a schematic diagram of the battery monitoring system 32 in accordance with one non-limiting aspect of the present disclosure. The battery monitoring system 32 may include a virtual cell model 40 and a physical cell model 42. The physical cell model 42 may be based on measurements taken physically from the battery pack 30, such as with one or more cell monitoring unit (CMUs) 44 of a sensing system 46. The physical cell model 42 may be operable for generating an indefinitive output based on a battery control unit (BCU) 48 or other feature receiving measurements taken with the sensing system 46 to represent a current (I) through the battery pack 30 and a battery voltage (U_{t,P}) across the battery pack 30. The virtual model 40 may be defined relative to a battery cell material having a comparatively more pronounced OCV-SOC curve, such as Nickel Cobalt Manganese (NCM) battery cell. The virtual cell model 40 may be used for generating a definitive output useful in estimating the SOC of the battery pack 30 without requiring the battery pack 30 to physically include an actual NCM or other battery cell comprised of a material with the more pronounced OCV-SOC curve. The battery pack 30 may be configured with the battery modules and the battery cells connected in series, however, the present disclosure fully contemplates the battery modules and/or cells being connected in other series and/or parallel configurations. The use of the battery monitoring system 32 is predominantly described with respect to calculating a battery SOC (SOC_{P}) for the battery pack 30 based on the current (I) and the battery voltage (U_{t,P}) for non-limiting purposes as the corresponding calculations and estimates may be similarly used at a more granular level, such as for the battery modules and/or the battery cells individually.

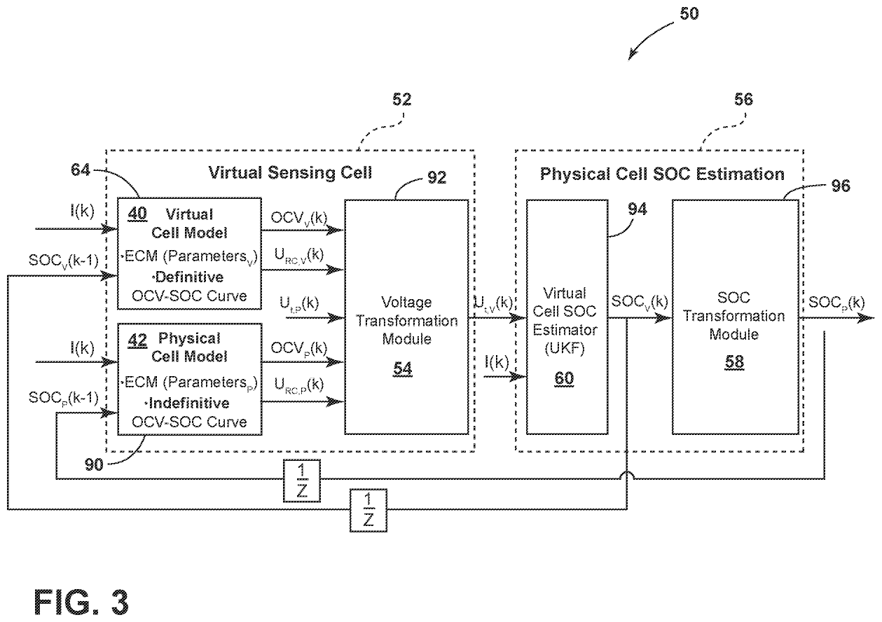

FIG. 3 illustrates a flowchart 50 of a method for monitoring the battery pack 30 in accordance with one non-limiting aspect of the present disclosure. The method is predominantly described with respect to operating the battery monitoring system 32 to facilitate estimating the battery SOC (SOC_{P}) for the battery pack 30. The method may be embodied in or facilitated with a controller or other features of the battery monitoring system 32 respectively operating onboard and/or offboard the vehicle 10 having one or more non-transitory computer-readable storage mediums for storing a plurality of non-transitory instructions, which when executed with one or more processors of the controller or additional controllers, may be operable for monitoring the battery pack in the described manner. The method may include a virtual sensing cell or process 52 whereby the virtual cell model 40 and the physical cell model 42 may cooperate with a voltage transformation module 54 to facilitate generating values for use with a physical cell SOC estimator 54 whereupon in SOC transformation module 56 and optionally a virtual cell SOC estimator 60 may correspondingly estimate the battery SOC (SOC_{P}). The contemplated method for estimating the battery SOC (SOC_{P}) is believed to be beneficial in enhancing the physical battery pack 30 with a virtual model observer whereby the use thereof may improve SOC accuracy, reduce hardware complexity, provide robustness against current management drift and noise, and provide desired levels of accuracy.

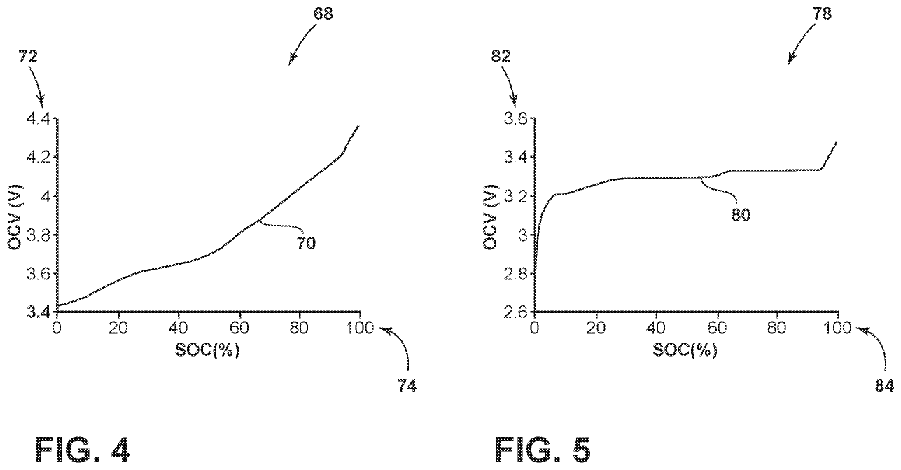

Block 64 relates to a virtual cell model process for generating a definitive output based on the current (I) and a definitive equivalent circuit model (ECM) for a virtual cell. The virtual cell may be a mathematical, logical, or other modeling constructs suitable for modeling characteristics for an NCM battery cell or other type of battery cell having a more pronounced OCV-SOC curve. FIG. 4 illustrates an example of a graph 68 for such a pronounced OCV-SOC curve 70, with a vertical axis 72 indicating OCV (V) and a horizontal axis 74 indicating SOC (%). The definitive ECM may define a plurality of virtual parameters (Parameters_{V}) for the virtual cell. The definitive output may include a virtual cell voltage (U_{RC,V}) across one or more R-C pairs of the definitive ECM and a virtual cell open circuit voltage (OCV_{V}) derived based on a virtual cell state of charge (SOC_{V}) and a definitive and relatively flat OCV-SOC curve for the physical cell. FIG. 5 illustrates an example of a graph 78 for such a relative flat OCV-SOC curve 80, with a vertical axis 82 indicating OCV (V) and a horizontal axis 84 indicating SOC (%). Block 90 relates to a physical cell model process for generating an indefinitive output based on the current (I) and an indefinitive ECM for the battery pack. The indefinitive ECM may define a plurality of physical parameters (Parameters_{P}) for the battery pack 30. The indefinitive output may include a physical cell voltage (U_{RC,p}) across one or more R-C pairs of the indefinitive ECM and an indefinitive open circuit voltage (OCV_{P}) derived based on an indefinitive OCV-SOC curve for the battery pack 30.

Block 92 relates to a voltage transformation module process for generating a virtual voltage (U_{t,V}) based on the battery voltage (U_{t,P}) and the definitive and indefinitive outputs. Block 94 relates to a virtual cell SOC estimator process configured for determining the virtual cell SOC (SOC_{V}) based on the virtual cell voltage (U_{t,V}) and the current (I). Block 96 relates to an SOC transformation module process for generating a battery SOC (SOC_{P}) for the battery pack based on the virtual cell SOC (SOC_{V}). At a time step k, the virtual cell model may be configured for determining the virtual cell voltage (U_{RC,V}(k)) according to:

$${U}_{RC , V} ( k ) = {e}^{- \frac{Δ t}{{R}_{1 , V} {C}_{1 , V}}} {U}_{RC , V} ( k - 1 ) + {R}_{1 , V} ( 1 - {e}^{- \frac{Δ t}{{R}_{1 , V} {C}_{1 , V}}} ) I ( k ) .$$

wherein the virtual parameters (Parameters_{V}) include R_{1,V} and C_{1,V}.

At the time step k, the virtual cell model may be configured for determining the virtual cell OCV (OCV_{V}(k)) based on the virtual cell SOC (SOC_{V}(k-1)) at a time step k-1.

At the time step k, the physical cell model may be configured for determining the physical cell voltage (U_{RC,P}(k)) according to:

$${U}_{RC , P} ( k ) = {e}^{- \frac{Δ t}{{R}_{1 , P} {C}_{1 , P}}} {U}_{RC , P} ( k - 1 ) + {R}_{1 , P} ( 1 - {e}^{- \frac{Δ t}{{R}_{1 , P} {C}_{1 , P}}} ) I ( k ) .$$

wherein the physical parameters (Parameters_{P}) include R_{1,P} and C_{1,P}.

At the time step k, the physical model may be configured for determining the physical cell OCV (OCV_{P}(k)) based on the physical cell SOC (SOC_{P}(k-1)) at a time step k-1.

The voltage transformation module may be configured for determining the virtual cell voltage (U_{t,V}) according to:

$${U}_{t , V} ( k ) = {OCV}_{V} ( k ) - {U}_{RC , V} ( k ) + \frac{{R}_{0 , V}}{{R}_{0 , P}} ( {U}_{t , P} ( k ) - {OCV}_{P} ( k ) + {U}_{RC , P} ( k ) ) .$$

wherein the virtual parameters (Parameters_{V}) include R_{0,V} and the physical parameters (Parameters_{P}) include R_{0,P}.

At the time step k, a Kalman Filter may be configured for determining the virtual cell SOC (SOC_{V}(k)) based on the virtual cell voltage (U_{t,V}(k)) and the current (I(k)).

At the time step k, the SOC transformation module may be configured for determining the battery SOC (SOC_{P}(k)) according to:

$${SOC}_{P} ( k ) = \frac{{Q}_{V}}{{Q}_{P}} [ {SOC}_{V} ( k ) - ( 1 - \frac{{Q}_{P}}{{Q}_{V}} ) ]$$

wherein the physical parameters (Parameters_{P}) include Q_{P} and the virtual parameters (Parameters_{V}) include Q_{V}.

The combination of virtual NCM and Kalman filter may be used to correct the SOC estimation according to the definite OCV-SOC curve of NCM in real time, thus mitigate the accumulation error caused by coulomb counting.

Coulomb counting accumulation error:

$$CC error = \frac{η}{Q} \cdot Δ I \cdot t$$

Virtual sensor model error:

$$VS error = \frac{1}{K} \cdot Δ I \cdot ( {R}_{0} + {R}_{1} ) \\ OCV = K \cdot SOC ; {U}_{RC} ( ∞ ) = {IR}_{1} \\ {U}_{t} = OCV - {U}_{RC} - {IR}_{0} = K \cdot SOC - {IR}_{1} - {IR}_{0} \\ SOC = \frac{1}{K} \cdot I \cdot ( {R}_{0} + {R}_{1} ) + \frac{1}{K} \cdot {U}_{t} \\ VS error = \frac{1}{K} \cdot Δ I \cdot ( {R}_{0} + {R}_{1} )$$

For example, for Coulomb counting (assuming η=1, Q=100 Ah=100*3600 As): CC error=2.7×10⁻⁶·ΔI·t and for virtual sensor model (assuming K=1, R₀=1 mOhm and R₁=2 mOhm): VS error=5×10⁻³·ΔI with VS error<CC error when t>1080 s, even when Coulomb counting has an accurate initial SOC.

While various embodiments have been described, the description is intended to be exemplary, rather than limiting and it will be apparent to those of ordinary skill in the art that many more embodiments and implementations are possible that are within the scope of the embodiments. Any feature of any embodiment may be used in combination with or substituted for any other feature or element in any other embodiment unless specifically restricted. Accordingly, the embodiments are not to be restricted except in light of the attached claims and their equivalents. Also, various modifications and changes may be made within the scope of the attached claims. Although several modes for carrying out the many aspects of the present teachings have been described in detail, those familiar with the art to which these teachings relate will recognize various alternative aspects for practicing the present teachings that are within the scope of the appended claims. It is intended that all matter contained in the above description or shown in the accompanying drawings shall be interpreted as illustrative and exemplary of the entire range of alternative embodiments that an ordinarily skilled artisan would recognize as implied by, structurally and/or functionally equivalent to, or otherwise rendered obvious based upon the included content, and not as limited solely to those explicitly depicted and/or described embodiments.

What is claimed is:

1. A battery monitoring system for a battery pack of a vehicle, comprising:
a sensing system configured for measuring a current (I) through the battery pack and a battery voltage (U_{t,P}) across the battery pack;
a virtual cell model configured for generating a definitive output based on the current (I) and a definitive equivalent circuit model (ECM) for a virtual cell, the definitive ECM defining a plurality of virtual parameters (Parameters_{V}) for the virtual cell, the definitive output including a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell;
a physical cell model configured for generating an indefinitive output based on the current (I) and an indefinitive ECM for the battery pack, the indefinitive ECM defining a plurality of physical parameters (Parameters_{P}) for the battery pack, the indefinitive output including an physical cell voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack; and
a voltage transformation module configured for generating a virtual voltage (U_{t,V}) based on the battery voltage (U_{t,P}) and the definitive and indefinitive outputs;
a virtual cell SOC estimator configured for determining the virtual cell SOC (SOC_{V}) based on the virtual cell voltage (U_{t,V}) and the current (I); and
an SOC transformation module configured for generating a battery SOC (SOC_{P}) for the battery pack based on the virtual cell SOC (SOC_{V}).

2. The battery monitoring system according to claim 1, wherein:
at a time step k, the virtual cell model is configured for determining the virtual cell voltage (URC,_{V}(k)) according to:
$${U}_{RC , V} ( k ) = {e}^{- \frac{Δ t}{{R}_{1 , V} {C}_{1 , V}}} {U}_{RC , V} ( k - 1 ) + {R}_{1 , V} ( 1 - {e}^{- \frac{Δ t}{{R}_{1 , V} {C}_{1 , V}}} ) I ( k )$$
wherein the virtual parameters (Parameters_{V}) include R_{1,V} and C_{1,V}.

3. The battery monitoring system according to claim 2, wherein:
at the time step k, the virtual cell model is configured for determining the virtual cell OCV (OCV_{V}(k)) based on the virtual cell SOC (SOC_{V}(k-1)) at a time step k-1.

4. The battery monitoring system according to claim 3, wherein:
at the time step k, the physical cell model is configured for determining the physical cell voltage (U_{RC,P}(k)) according to:
$${U}_{RC , P} ( k ) = {e}^{- \frac{Δ t}{{R}_{1 , P} {C}_{1 , P}}} {U}_{RC , P} ( k - 1 ) + {R}_{1 , P} ( 1 - {e}^{- \frac{Δ t}{{R}_{1 , P} {C}_{1 , P}}} ) I ( k )$$
wherein the physical parameters (Parameters_{P}) include R_{1,P} and C_{1,P}.

5. The battery monitoring system according to claim 4, wherein:
at the time step k, the physical model is configured for determining the physical cell OCV (OCV_{P}(k)) based on the physical cell SOC (SOC_{P}(k-1)) at a time step k-1.

6. The battery monitoring system according to claim 5, wherein:
the voltage transformation module configured for determining the virtual cell voltage (U_{t,V}) according to:
$${U}_{t , V} ( k ) = {OCV}_{V} ( k ) - {U}_{RC , V} ( k ) + \frac{{R}_{0 , V}}{{R}_{0 , P}} ( {U}_{t , P} ( k ) - {OCV}_{P} ( k ) + {U}_{RC , P} ( k ) )$$
wherein the virtual parameters (Parameters_{V}) include R_{0,V} and the physical parameters (Parameters_{P}) include R_{0,P}.

7. The battery monitoring system according to claim 6, wherein:
at the time step k, a Kalman Filter is configured for determining the virtual cell SOC (SOC_{V}(k)) based on the virtual cell voltage (U_{t,V}(k)) and the current (I(k)).

8. The battery monitoring system according to claim 7, wherein:
at the time step k, the SOC transformation module is configured for determining the battery SOC (SOC_{P}(k)) according to:
$${SOC}_{P} ( k ) = \frac{{Q}_{V}}{{Q}_{P}} [ {SOC}_{V} ( k ) - ( 1 - \frac{{Q}_{P}}{{Q}_{V}} ) ]$$
wherein the physical parameters (Parameters_{P}) include Q_{P} and the virtual parameters (Parameters_{V}) include Q_{V}.

9. A non-transitory computer-readable storage medium for storing a plurality of non-transitory instructions, which when executed with one or more processors, are operable for monitoring a battery pack, wherein the non-transitory instructions are operable for:
determining a current (I) through the battery pack and a battery voltage (U_{t,P}) across the battery pack;
generating a definitive output based on the current (I) and a definitive equivalent circuit model (ECM) for a virtual cell, the definitive ECM defining a plurality of virtual parameters (Parameters_{V}) for the virtual cell, the definitive output including a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell; and
generating an indefinitive output based on the current (I) and an indefinitive ECM for the battery pack, the indefinitive ECM defining a plurality of physical parameters (Parameters_{P}) for the battery pack, the indefinitive output including an indefinitive voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack.

10. The non-transitory computer-readable storage medium according to claim 9, wherein the non-transitory instructions are operable for:
generating a virtual voltage (U_{t,V}) based on the battery voltage (U_{t,P}), and the definitive and indefinitive outputs;
determining the virtual cell SOC (SOC_{V}) based on the virtual cell voltage (U_{t,V}) and the current (I); and
generating a battery SOC (SOC_{P}) for the battery pack based on the virtual cell SOC (SOC_{V}).

11. The non-transitory computer-readable storage medium according to claim 10, wherein the non-transitory instructions are operable for:
at a time step k, determining the virtual cell voltage (U_{RC,V}(k)) according to:
$${U}_{RC , V} ( k ) = {e}^{- \frac{Δ t}{{R}_{1 , V} {C}_{1 , V}}} {U}_{RC , V} ( k - 1 ) + {R}_{1 , V} ( 1 - {e}^{- \frac{Δ t}{{R}_{1 , V} {C}_{1 , V}}} ) I ( k )$$
wherein the virtual parameters (Parameters_{V}) include R_{1,V} and C_{1,V}.

12. The non-transitory computer-readable storage medium according to claim 11, wherein the non-transitory instructions are operable for:
at the time step k, determining the virtual cell OCV (OCV_{V}(k)) based on the virtual cell SOC (SOC_{V}(k-1)) at a time step k-1.

13. The non-transitory computer-readable storage medium according to claim 12, wherein the non-transitory instructions are operable for:
at the time step k, determining the physical cell voltage (U_{RC,P}(k)) according to:
$${U}_{RC , P} ( k ) = {e}^{- \frac{Δ t}{{R}_{1 , P} {C}_{1 , P}}} {U}_{RC , P} ( k - 1 ) + {R}_{1 , P} ( 1 - {e}^{- \frac{Δ t}{{R}_{1 , P} {C}_{1 , P}}} ) I ( k )$$
wherein the physical parameters (Parameters_{P}) include R_{1,P} and C_{1,P}.

14. The non-transitory computer-readable storage medium according to claim 13, wherein the non-transitory instructions are operable for:
at the time step k, determining the physical cell OCV (OCV_{P}(k)) based on the physical cell SOC (SOC_{P}(k-1)) at a time step k-1.

15. The non-transitory computer-readable storage medium according to claim 14, wherein the non-transitory instructions are operable for:
determining the virtual cell voltage (U_{t,V}) according to:
$${U}_{t , V} ( k ) = {OCV}_{V} ( k ) - {U}_{RC , V} ( k ) + \frac{{R}_{0 , V}}{{R}_{0 , P}} ( {U}_{t , P} ( k ) - {OCV}_{P} ( k ) + {U}_{RC , P} ( k ) )$$
wherein the virtual parameters (Parameters_{V}) include R_{0,V} and the physical parameters (Parameters_{P}) include R_{0,P}.

16. The non-transitory computer-readable storage medium according to claim 15, wherein the non-transitory instructions are operable for:
at the time step k, determining the virtual cell SOC (SOC_{V}(k)) based on the virtual cell voltage (U_{t,V}(k)) and the current (I(k)).

17. The non-transitory computer-readable storage medium according to claim 16, wherein the non-transitory instructions are operable for:
at the time step k, determining the battery SOC (SOC_{P}(k)) according to:
$${SOC}_{P} ( k ) = \frac{{Q}_{V}}{{Q}_{P}} [ {SOC}_{V} ( k ) - ( 1 - \frac{{Q}_{P}}{{Q}_{V}} ) ]$$
wherein the physical parameters (Parameters_{P}) include Q_{P} and the virtual parameters (Parameters_{V}) include Q_{V}.

18. A battery monitoring system for a battery pack of an electric vehicle, comprising:
a virtual cell model configured for generating a definitive output based on a current (I) through the battery pack and a definitive equivalent circuit model (ECM) for a virtual cell; and
a physical cell model configured for generating an indefinitive output based on the current (I) and an indefinitive ECM for the battery pack; and
a state of charge (SOC) transformation module configured for generating a battery SOC (SOC_{P}) for the battery pack based at least in part on the definitive and indefinitive outputs.

19. The battery monitoring system according to claim 18, wherein:
the definitive ECM is defining a plurality of virtual parameters (Parameters_{V}) for the virtual cell;
the definitive output includes a virtual cell voltage (U_{RC,V}) across one or more R-C pairs of the definitive ECM and a virtual cell open circuit voltage (OCV_{V}) derived based on a virtual cell state of charge (SOC_{V}) and a definitive open circuit voltage state of charge (OCV-SOC) curve for the virtual cell;
the indefinitive ECM defining a plurality of physical parameters (Parameters_{P}) for the battery pack; and
the indefinitive output includes an indefinitive voltage (U_{RC,p}) across one or more R-C pairs of the indefinitive ECM and an indefinitive open circuit voltage (OCV_{P}) derived based on an indefinitive open circuit voltage state of charge (OCV-SOC) curve for the battery pack.

20. The battery monitoring system according to claim 19, further comprising:
a voltage transformation module configured for generating a virtual voltage (U_{t,V}) based on the battery voltage (U_{t,P}) and the definitive and indefinitive outputs;
a virtual cell SOC estimator configured for determining the virtual cell SOC (SOC_{V}) based on the virtual cell voltage (U_{t,V}) and the current (I); and
an SOC transformation module configured for generating the battery SOC (SOC_{P}) for the battery pack based on the virtual cell SOC (SOC_{V}).
